(19) United States
(12) Patent Application Publication
(10) Pub. No.: US 2026/0218364 A1
(43) Pub. Date: Jul. 30, 2026

(54) COATING STRUCTURE

(71) Applicant: SAMSUNG ELECTRONICS CO., LTD., Suwon-si (KR)

(72) Inventors: In-Hwan LEE, Seoul-si (KR); Kang-Bin BAE, Icheon-si (KR); Jung Kyun NA, Suwon-si (KR); Byeong Sang KIM, Suwon-si (KR); Seung-Ri KIM, Suwon-si (KR); Youn Seon WANG, Suwon-si (KR)

(73) Assignees: SAMSUNG ELECTRONICS CO., LTD., Suwon-si (KR); Korea University Research and Business Foundation, Seoul (KR)

(21) Appl. No.: 19/180,518

(22) Filed: Apr. 16, 2025

(30) Foreign Application Priority Data
Dec. 5, 2024 (KR) 10-2024-0179571

(51) Int. Cl. C23C 14/00; C23C 14/06; C23C 14/08; C23C 14/30

(52) U.S. Cl. CPC C23C 14/0036; C23C 14/0694; C23C 14/083; C23C 14/30

(57) ABSTRACT

A coating structure includes: a buffer layer on a base material; and an exposed layer on the buffer layer, wherein each of the buffer layer and the exposed layer includes a composite material including at least a first metal element, a second metal element, and a non-metal element.

### CROSS-REFERENCE TO RELATED APPLICATION

This application is based on and claims priority under 35 U.S.C. § 119 to Korean Patent Application No. 10-2024-0179571, filed on Dec. 5, 2024, in the Korean Intellectual Property Office, the disclosure of which is incorporated by reference herein in its entirety.

### BACKGROUND

### 1. Field

The present disclosure relates to a coating structure.

### 2. Description of Related Art

Semiconductor device or a display device is manufactured through various substrate processing processes on a substrate such as a wafer. The substrate is processed in each of a plurality of substrate processing processes in which each processing process is performed, so that the substrate is to be manufactured as the semiconductor device or the display device.

Among these substrate processing apparatuses, in a chemical vapor deposition apparatus, chemical vapor deposition is performed for a substrate. The chemical vapor deposition apparatus includes a heater to increase a temperature of the substrate for activation of reaction. The heater of the chemical vapor deposition apparatus is coated with a coating material for protection.

In a plasma cleaning process, a surface of the substrate is cleaned by using plasma during the substrate processing process. In the plasma cleaning process, the surface of the substrate is cleaned using the plasma. In addition, the substrate processing apparatus may be also cleaned in the plasma cleaning process. When the substrate processing apparatus is cleaned with the plasma, a surface and other parts in a chamber of the substrate processing apparatus are cleaned using radicals having high activity in a plasma environment having a low power. In this plasma cleaning process, fluorine (F)-based plasma is used.

In one example of the related art, the heater of the chemical vapor deposition apparatus is coated with yttrium oxide (Y₂O₃) as a coating material. Yttrium oxide has a bixbyite crystal structure, and has oxygen vacancy in which oxygen is empty. In addition, when the heater of the chemical vapor deposition apparatus is cleaned using the fluorine-based plasma, fluorine is diffused into the coating of the heater through the oxygen vacancy of the crystal structure of yttrium oxide.

When the fluorine is diffused into the coating of the heater of the chemical vapor deposition apparatus, ‘yttrium oxyflouride’ (YOF) is generated, so that a thermal expansion coefficient of the coating of the heater is increased. In addition, as the fluorine is diffused into yttrium oxide, the thermal expansion coefficient of the coating of the heater becomes larger, so that a difference between the thermal expansion coefficient of the coating of the heater and a thermal expansion coefficient of the heater is more increased.

In addition, stress is increased due to the difference between the thermal expansion coefficient of the coating of the heater and the thermal expansion coefficient of the heater. When thermal shock occurs in this state, cracks occur in the coating of the heater or the coating is peeled off from the heater.

When cracks occur in the coating of the heater of the chemical vapor deposition apparatus or the coating is peeled off from the heater, problems may occur, for example, a temperature of the heater may be uneven, particles may occur, and the substrate and the heater may be damaged.

In another example of the related art, to solve the problems in the above example of the related art, an yttrium oxyfluoride layer was formed on an yttrium oxide layer when the heater was coated, the yttrium oxide coating of the heater was fluorinated to generate yttrium oxyfluoride on the yttrium oxide layer, or the heater was coated with yttrium oxyfluoride as a coating material. This method could more reduce the diffusion of fluorine in the coating of the heater than before, but could not prevent the thermal expansion coefficient of the coating of the heater from being increased due to fluorine. Furthermore, due to stress caused by the difference between the thermal expansion coefficient of the coating of the heater and the thermal expansion coefficient of the heater, cracks could not be prevented from occurring in the coating structure and the coating could not be prevented from being peeled off from the heater.

### SUMMARY

Provided is a coating structure that has a stable crystal structure and is thermally stable.

The aspects of the present disclosure are not limited to those mentioned above. Additional aspects of the present disclosure, which are not mentioned herein, will be clearly understood by those skilled in the art from the following description of the present disclosure.

According to an aspect of the disclosure, a coating structure includes: a buffer layer on a base material; and an exposed layer on the buffer layer, wherein each of the buffer layer and the exposed layer includes a composite material including at least a first metal element, a second metal element, and a non-metal element.

According to an aspect of the disclosure, a coating structure includes: a buffer layer on a base material in a heater of a chemical vapor deposition apparatus; and an exposed layer on the buffer layer, wherein each of the buffer layer and the exposed layer includes at least a first metal element, a second metal element, and oxygen, wherein a content of the metal element (the first metal element and/or the second metal element) in the buffer layer is greater than a content of the metal element in the exposed layer, and wherein a content of the oxygen in the exposed layer is greater than a content of the oxygen in the buffer layer.

According to an aspect of the disclosure, a coating structure includes: a buffer layer on a base material; and an exposed layer on the buffer layer, wherein each of the buffer layer and the exposed layer includes at least a first metal element, a second metal element, and oxygen, wherein a content of the metal element in the buffer layer is greater than a content of the metal element in the exposed layer, wherein a content of the oxygen in the exposed layer is greater than a content of the oxygen in the buffer layer, wherein the buffer layer and the exposed layer are formed by solid-solutioning a second metal element-based material including the second metal element and the oxygen into a first metal element-based material including the first metal element and the oxygen, wherein the first metal element is yttrium (Y), wherein the first metal element-based material includes at least one of yttrium oxide (Y2O3) and yttrium oxyfluoride (YOF), wherein the second metal element includes at least one of cerium (Ce), aluminum (Al), and hafnium (Hf), wherein the second metal element-based material includes at least one of cerium oxide (CeO2), aluminum oxide (Al2O3), and aluminum oxyfluoride (AlOF), wherein a fraction of the oxygen in the buffer layer is 0.1 or more and 0.3 or less, wherein a fraction of the oxygen in the exposed layer is 0.5 or more and 0.8 or less, wherein a thickness of the buffer layer is 20 nm or more and 500 nm or less, and wherein a thickness of the exposed layer is 2 μm or more and 10 μm or less.

Specific details of other embodiments are included in the detailed description and drawings.

### BRIEF DESCRIPTION OF THE DRAWINGS

The above and other aspects and features of the present disclosure will become more apparent by describing in detail embodiments thereof with reference to the attached drawings, in which:

FIG. 1 illustrates a coating structure according to some embodiments of the present disclosure;

FIG. 2 illustrates that the coating structure of FIG. 1 is formed on the base material by physical vapor deposition;

FIG. 3 illustrates that a buffer layer is disposed to be deposited on the base material by physical vapor deposition of FIG. 2;

FIG. 4 illustrates that an exposed layer is disposed to be deposited on the buffer layer by physical vapor deposition of FIG. 2;

FIG. 5 is a Scanning Electron Microscope (SEM)-Energy Dispersive Spectroscopy (EDS) analysis result of an example of the coating structure of FIG. 1;

FIG. 6 illustrates etching test results of other coating structures and an example of the coating structure of FIG. 1; and

FIG. 7 illustrates results of thermal shock tests for another coating structure and an example of the coating structure of FIG. 1.

### DETAILED DESCRIPTION

Although terms such as first, second, upper, and lower are used herein to describe various elements or components, it is obvious that these elements or components are not limited by the terms. Rather, the terms are merely used herein to distinguish one element or component from another element or component. Therefore, it is obvious that a first element or component as mentioned below may also be a second element or component within the technical spirit of the present disclosure. Further, it is obvious that a lower element or component as mentioned below may also be an upper element or component within the technical spirit of the present disclosure.

Hereinafter, embodiments of the present disclosure are described in detail with reference to the attached drawings. The same reference numerals are used for the same components in the drawings, and duplicate descriptions of the same reference numerals are omitted.

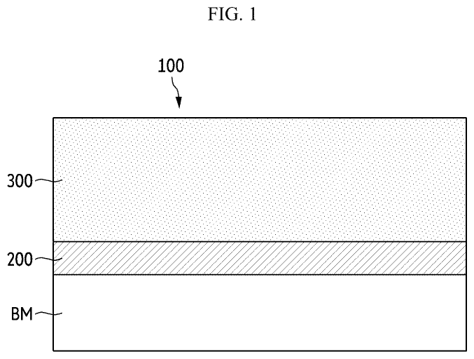

FIG. 1 illustrates a coating structure according to some embodiments of the present disclosure.

In FIG. 1, a coating structure 100 may protect a base material BM to which the coating structure 100 is applied. In other words, the coating structure 100 may be coated on a surface of the base material BM to protect the base material BM. For example, the base material BM protected by the coating structure 100 (that is applied to the base material BM) may be included in a heater of a chemical vapor deposition apparatus. In other words, the base material BM may form at least a portion of the heater of the chemical vapor deposition apparatus, but the base material BM protected by the coating structure 100 (that is applied to the base material BM) is not limited to the above example embodiment.

The base material BM protected by the coating structure 100 (that is applied to the base material BM) may include ceramic. For example, the base material BM may include one or more of aluminum oxide (Al₂O₃) and aluminum nitride (AlN), but components included in the base material BM are not limited to the above example embodiment.

The coating structure 100 includes a buffer layer 200, an exposed layer 300, etc

The buffer layer 200 may be disposed on the base material BM. The buffer layer 200 may be disposed on the base material BM so that it is to be adhered to the base material BM. The buffer layer 200 may be disposed to be deposited on the base material BM by physical vapor deposition (PVD).

For example, the physical vapor deposition method used for the buffer layer 200 to be disposed on the base material BM may be reactive sputtering or electron beam physical vapor deposition (EB-PVD). But the physical vapor deposition method used for the buffer layer 200 to be disposed on the base material BM is not limited to the above example embodiment.

The buffer layer 200 may include a composite material containing two or more metal elements and a non-metal element. For example, the buffer layer 200 may include a composite material containing a first metal, a second metal, and oxygen as a non-metal element. Since the buffer layer 200 includes a composite material containing two or more metal elements and a non-metal element as described above, the buffer layer 200 may have a stable crystal structure. In other words, the buffer layer 200 may have a relatively small vacancy that is an empty space in the crystal structure.

Since the vacancy in the crystal structure is relatively small, it is possible to prevent elements, which enter the coating structure 100 from the outside, from being diffused in the buffer layer 200. In addition, a thermal expansion coefficient of the buffer layer 200 may be prevented from being increased by diffusion of the elements entering the coating structure 100 from the outside, so that a difference between the thermal expansion coefficient of the buffer layer 200 and a thermal expansion coefficient of the base material BM may be prevented from being increased. In addition, it is possible to prevent occurrence of cracks in the coating structure 100 or peeling-off of the coating structure 100 from the base material BM, which is caused due to stress caused by the difference between the thermal expansion coefficient of the buffer layer 200 and the thermal expansion coefficient of the base material BM. In other words, resistance of the coating structure 100 to thermal shock is increased, so that the coating structure 100 may be thermally stable.

A content of the metal elements in the buffer layer 200 may be greater than a content of the metal elements in the exposed layer 300. In other words, since the buffer layer 200 includes more metal elements than the exposed layer 300, the buffer layer 200 may be metal rich compared to the exposed layer 300. Since the buffer layer 200 includes more metal elements than the exposed layer 300, the difference between the thermal expansion coefficient of the buffer layer 200 and the thermal expansion coefficient of the base material BM may be smaller than a difference between a thermal expansion coefficient of the exposed layer 300 and the thermal expansion coefficient of the base material BM. In other words, the difference in the thermal expansion coefficient from the base material BM may be gradually reduced from the exposed layer 300 toward the buffer layer 200. As described above, as the difference in the thermal expansion coefficient from the base material BM is gradually reduced from the exposed layer 300 toward the buffer layer 200, the buffer layer 200 may buffer thermal shock between the exposed layer 300 and the base material BM. Also, the resistance of the coating structure 100 to thermal shock may be increased, and the coating structure 100 may be thermally stable.

Since the buffer layer 200 includes more metal elements than the exposed layer 300, the buffer layer 200 may have a greater adhesive force than the exposed layer 300. Furthermore, the buffer layer 200 may be better adhered to the base material BM than the exposed layer 300. In addition, since the exposed layer 300 is adhered to the base material BM by the buffer layer 200 having a greater adhesive force than the exposed layer 300, the coating structure 100 may be stably disposed on the base material BM.

Since the buffer layer 200 includes more metal elements than the exposed layer 300, the buffer layer 200 may be more flexible than the exposed layer 300. Since the buffer layer 200 is more flexible than the exposed layer 300, the buffer layer 200 may buffer shock transferred to the base material BM through the exposed layer 300. For example, the buffer layer 200 may prevent crack propagation from a surface of the coating structure 100.

Since the buffer layer 200 includes more metal elements than the exposed layer 300, the buffer layer 200 may include elements entering the coating structure 100 from the outside. As described above, since the buffer layer 200 may include elements entering the coating structure 100 from the outside, it is possible to prevent the elements entering the coating structure 100 from the outside from being diffused into the base material BM.

A content of the non-metal element of the buffer layer 200 may be smaller than a content of the non-metal element of the exposed layer 300. In other words, the buffer layer 200 may include a non-metal element smaller than the exposed layer 300. The buffer layer 200 may include oxygen (O) as a non-metal element, and an oxygen content of the buffer layer 200 may be smaller than an oxygen content of the exposed layer 300.

The buffer layer 200 may include a first metal element, a second metal element, and oxygen. In addition, the buffer layer 200 may be formed by solid-solutioning a second metal element-based material containing a second metal element and oxygen into a first metal element-based material containing a first metal element and oxygen. As described above, since the buffer layer 200 is formed by solid-solutioning the second metal element-based material into the first metal element-based material, the buffer layer 200 may have a thermal expansion coefficient between a thermal expansion coefficient of the first metal element-based material and a thermal expansion coefficient of the second metal element-based material. By physical vapor deposition, the second metal element-based material may be solid-solutioned into the first metal element-based material, and the buffer layer 200 may be disposed to be deposited on the base material BM.

The first metal element included in the buffer layer 200 may be yttrium (Y). Also, the first metal element-based material may include one or more of yttrium oxide (Y₂O₃) and yttrium oxyfluoride (YOF).

The second metal element included in the buffer layer 200 may include one or more of cerium (Ce), aluminum (Al), and hafnium (Hf). In addition, the second metal element-based material may include one or more of cerium oxide (CeO₂), aluminum oxide (Al₂O₃), and aluminum oxyfluoride (AlOF).

In addition, one or more of cerium oxide, aluminum oxide and aluminum oxyfluoride may be solid-solutioned into one or more of yttrium oxide and yttrium oxyfluoride, so that the buffer layer 200 may be formed.

An oxygen fraction of the buffer layer 200 may be 0.1 or more and 0.3 or less. When the oxygen fraction of the buffer layer 200 is smaller than 0.1, the metal element may be excessively included in the buffer layer 200. When the metal element is excessively included in the buffer layer 200, durability of the coating structure 100 may be deteriorated. When the oxygen fraction of the buffer layer 200 is greater than 0.3, the metal element may not be sufficiently included in the buffer layer 200. When the metal element is not sufficiently included in the buffer layer 200, the aforementioned effect of the buffer layer 200 may not be exhibited. In other words, when the metal element is not sufficiently included in the buffer layer 200, the buffer layer 200 may not buffer the thermal shock between the exposed layer 300 and the base material BM. Also, when the metal element is not sufficiently included in the buffer layer 200, the buffer layer 200 may not have a greater adhesion than that of the exposed layer 300. Also, when the metal element is not sufficiently included in the buffer layer 200, the buffer layer 200 may not buffer the shock transferred to the base material BM through the exposed layer 300. In addition, when the metal element is not sufficiently included in the buffer layer 200, the elements entering the coating structure 100 from the outside may not be prevented from being diffused into the base material BM.

A thickness of the buffer layer 200 may be 20 nm or more and 50 nm or less. When the thickness of the buffer layer 200 is smaller than 20 nm, the aforementioned effect of the buffer layer 200 may not be exhibited. Even when the thickness of the buffer layer 200 is greater than 500 nm, the aforementioned effect of the buffer layer 200 may not be exhibited.

The exposed layer 300 may be exposed to the outside. Since the exposed layer 300 is exposed to the outside, the exposed layer 300 may be directly affected by the outside, and external elements may enter the coating structure 100 through the exposed layer 300. For example, when the coating structure 100 is applied to the heater of the chemical vapor deposition apparatus, the chemical vapor deposition apparatus may be cleaned by fluorine (F)-based plasma, and fluorine may enter the coating structure 100 through the exposed layer 300 during cleaning by the fluorine-based plasma.

The exposed layer 300 may be disposed on the buffer layer 200. As the exposed layer 300 is disposed on the buffer layer 200, the exposed layer 300 may be exposed to the outside. The exposed layer 300 may be disposed on the buffer layer 200 so that it may be adhered to the buffer layer 200. The exposed layer 300 may be disposed to be deposited on the buffer layer 200 by physical vapor deposition.

In an embodiment, the buffer layer 200 may be disposed on the base material BM by physical vapor deposition as described above. Therefore, after the buffer layer 200 is disposed on the base material BM by physical vapor deposition, the exposed layer 300 may be disposed on the buffer layer 200 by physical vapor deposition. In other words, by physical vapor deposition, the buffer layer 200 may be disposed on the base material BM and the exposed layer 300 may be disposed on the buffer layer 200.

The exposed layer 300 may include a composite material containing two or more metal elements and a non-metal element. For example, the exposed layer 300 may include a composite material containing a first metal, a second metal, and oxygen as a non-metal element. Since the exposed layer 300 includes a composite material containing two or more metal elements and a non-metal element as described above, the exposed layer 300 may have a stable crystal structure. In other words, the exposed layer 300 may have a relatively small vacancy that is an empty space in the crystal structure.

Since the vacancy in the crystal structure is relatively small, it is possible to prevent external elements from being diffused in the exposed layer 300. In addition, the thermal expansion coefficient of the exposed layer 300 may be prevented from being increased by diffusion of the external elements in the exposed layer 300, so that a difference between the thermal expansion coefficient of the exposed layer 300 and the thermal expansion coefficient of the buffer layer 200 may be prevented from being increased. In addition, it is possible to prevent occurrence of cracks in the coating structure 100 or peeling-off of the coating structure 100 from the base material BM, which is caused due to stress caused by the difference between the thermal expansion coefficient of the exposed layer 300 and the thermal expansion coefficient of the buffer layer 200. In other words, resistance of the coating structure 100 to thermal shock is increased, so that the coating structure 100 may be thermally stable.

As described above, the buffer layer 200 may also include a composite material containing two or more metal elements and a non-metal element in the same manner as the exposed layer 300. In other words, components of the exposed layer 300 may be the same as or similar to those of the buffer layer 200. Since the components of the exposed layer 300 are the same as or similar to those of the buffer layer 200, the difference between the thermal expansion coefficient of the exposed layer 300 and the thermal expansion coefficient of the buffer layer 200 may be small.

Since the difference between the thermal expansion coefficient of the exposed layer 300 and the thermal expansion coefficient of the buffer layer 200 is small, cracks may be prevented from occurring in the coating structure 100 or the coating structure 100 may be prevented from being peeled off from the base material BM due to stress caused by the difference between the thermal expansion coefficient of the exposed layer 300 and the thermal expansion coefficient of the buffer layer 200. In other words, resistance of the coating structure 100 to thermal shock may be increased, and the coating structure 100 may be thermally stable.

A content of the non-metal element of the exposed layer 300 may be greater than a content of the non-metal element of the buffer layer 200. In other words, the exposed layer 300 may include more non-metal elements than the buffer layer 200. Since the content of the non-metal element of the exposed layer 300 is more than that of the buffer layer 200, the exposed layer 300 may have a more stable crystal structure than the buffer layer 200.

The non-metal element may fill the vacancy that is an empty space in the crystal structure. Therefore, the exposed layer 300, which includes more non-metal elements than the buffer layer 200, may have a more stable crystal structure than the buffer layer 200. In addition, even when exposed to the outside, external elements may be prevented from being diffused in the exposed layer 300. In addition, the thermal expansion coefficient of the exposed layer 300 may be prevented from being increased by diffusion of the external elements in the exposed layer 300, so that the difference between the thermal expansion coefficient of the exposed layer 300 and the thermal expansion coefficient of the buffer layer 200 may be prevented from being increased. In addition, cracks may be prevented from occurring in the coating structure 100 or the coating structure 100 may be prevented from being peeled off from the base material BM due to stress caused by the difference between the thermal expansion coefficient of the exposed layer 300 and the thermal expansion coefficient of the buffer layer 200. In other words, the resistance of the coating structure 100 to thermal shock is increased, so that the coating structure 100 may be thermally stable.

The exposed layer 300 may include oxygen as a non-metal element as will be described later, and the oxygen content of the exposed layer 300 may be greater than the oxygen content of the buffer layer 200.

The content of the metal element in the exposed layer 300 may be smaller than the content of the metal element in the buffer layer 200. In other words, the exposed layer 300 may include a metal element having a smaller content than that of the buffer layer 200.

The exposed layer 300 may include a first metal element, a second metal element, and oxygen. In addition, the exposed layer 300 may be formed by solid-solutioning a second metal element-based material containing a second metal element and oxygen into a first metal element-based material containing a first metal element and oxygen. As described above, since the exposed layer 300 is formed by solid-solutioning the second metal element-based material into the first metal element-based material, the exposed layer 300 may have a thermal expansion coefficient between a thermal expansion coefficient of the first metal element-based material and a thermal expansion coefficient of the second metal element-based material. By physical vapor deposition, the second metal element-based material may be solid-solutioned into the first metal element-based material, and the exposed layer 300 may be disposed to be deposited on the buffer layer 200.

As described above, by physical vapor deposition, the second metal element-based material may be solid-solutioned into the first metal element-based material and the buffer layer 200 may be disposed to be deposited on the base material BM. Therefore, after the second metal element-based material is solid-solutioned into the first metal element-based material and the buffer layer 200 is disposed to be deposited on the base material BM by physical vapor deposition, the second metal element-based material may be solid-solutioned into the first metal element-based material and the exposed layer 300 may be disposed to be deposited on the buffer layer 200 by physical vapor deposition. In other words, by physical vapor deposition, the second metal element-based material may be solid-solutioned into the first metal element-based material and the buffer layer 200 and the exposed layer 300 may be disposed to be sequentially deposited on the base material BM.

The first metal element included in the exposed layer 300 may be yttrium. Also, the first metal element-based material may include one or more of yttrium oxide and yttrium oxyfluoride.

The second metal element included in the exposed layer 300 may include one or more of cerium, aluminum, and hafnium. In addition, the second metal element-based material may include one or more of cerium oxide, aluminum oxide, and aluminum oxyfluoride.

In addition, one or more of cerium oxide, aluminum oxide and aluminum oxyfluoride may be solid-solutioned into one or more of yttrium oxide and yttrium oxyfluoride, so that the exposed layer 300 may be formed.

An oxygen fraction of the exposed layer 300 may be 0.5 or more and 0.8 or less. When the oxygen fraction of the exposed layer 300 is smaller than 0.5, oxygen may not be sufficiently included in the exposed layer 300. When oxygen is not sufficiently included in the exposed layer 300, the aforementioned effect of the exposed layer 300 may not be exhibited. In other words, when oxygen is not sufficiently included in the exposed layer 300, the exposed layer 300 may have a crystal structure that is not more stable than that of the buffer layer 200. Also, when oxygen is not sufficiently included in the exposed layer 300, external elements may not be prevented from being diffused in the exposed layer 300. Also, when oxygen is not sufficiently included in the exposed layer 300, the thermal expansion coefficient of the exposed layer 300 may not be prevented from being increased by diffusion of the external elements in the exposed layer 300. Also, when oxygen is not sufficiently included in the exposed layer 300, the difference between the thermal expansion coefficient of the exposed layer 300 and the thermal expansion coefficient of the buffer layer 200 may not be prevented from being increased. Also, when oxygen is not sufficiently included in the exposed layer 300, cracks may not be prevented from occurring in the coating structure 100 or the coating structure 100 may not be prevented from being peeled off from the base material BM due to stress caused by the difference between the thermal expansion coefficient of the exposed layer 300 and the thermal expansion coefficient of the buffer layer 200. When the oxygen fraction of the exposed layer 300 is greater than 0.8, oxygen may not be included in the exposed layer 300.

A thickness of the exposed layer 300 may be 2 μm or r more and 10 μm or less. When the thickness of the exposed layer 300 is smaller than 2 μm, lifespan of the coating structure 100 may be shortened. When the thickness of the exposed layer 300 is greater than 10 μm, cracks may occur in the exposed layer 300 during formation of the exposed layer 300. For example, when the thickness of the exposed layer 300 is greater than 10 μm during formation of the exposed layer 300 by physical vapor deposition, cracks may occur in the exposed layer 300.

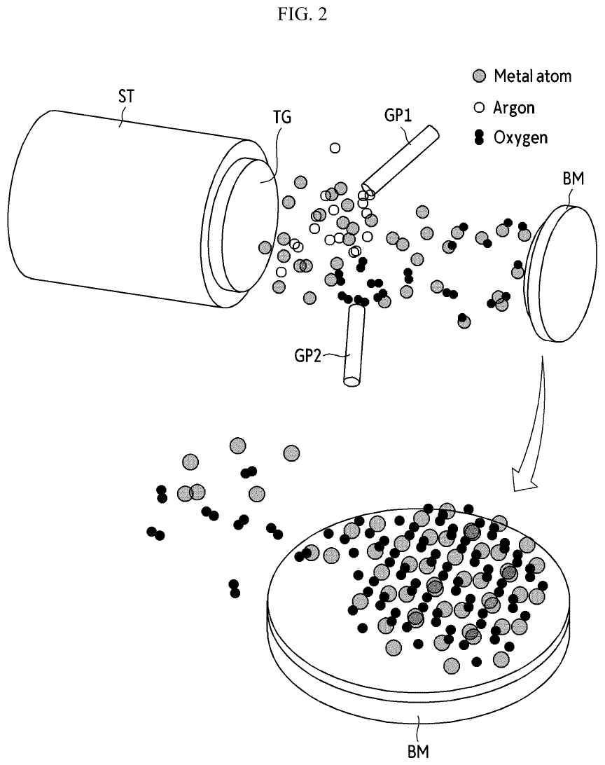

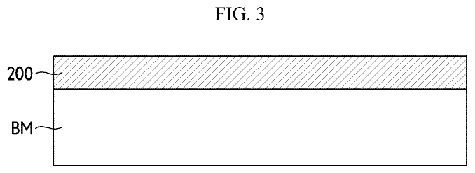

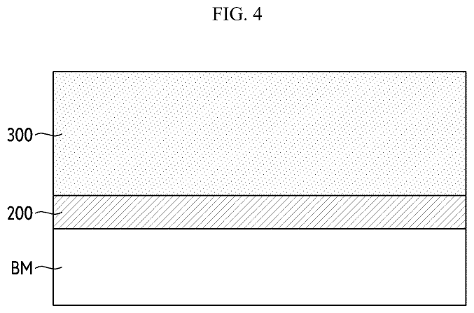

FIG. 2 illustrates that the coating structure of FIG. 1 is formed on the base material by physical vapor deposition, FIG. 3 illustrates that a buffer layer is disposed to be deposited on the base material by physical vapor deposition of FIG. 2, and FIG. 4 illustrates that an exposed layer is disposed to be deposited on the buffer layer by physical vapor deposition of FIG. 2.

The coating structure 100 of FIG. 1 may be formed by physical vapor deposition. When the coating structure 100 is formed by physical vapor deposition, a heat treatment such as annealing may not be required separately after formation of the coating structure 100.

FIG. 2 illustrates that the coating structure 100 is formed on the base material BM by reactive sputtering in the physical vapor deposition method. In addition, the coating structure 100 may be formed by electron beam physical vapor deposition in the physical vapor deposition method. But the physical vapor deposition method in which the coating structure 100 is formed is not limited to the above example embodiment.

In FIG. 2, a vacuum may be formed in a chamber. A target TG may be disposed in the chamber, in which the vacuum is formed, by being supported by a target support member ST to face the base material BM. The target TG may include a first metal element and a second metal element, or may include a first metal-based material and a second metal element. For example, the target TG may include yttrium and cerium, yttrium and aluminum, or yttrium and hafnium. Also, the target TG may include yttrium oxide and cerium, yttrium oxide and aluminum, or yttrium oxide and hafnium. In addition, the target TG may include yttrium oxyfluoride and cerium, yttrium oxyfluoride and aluminum, or yttrium oxyfluoride and hafnium.

When the target TG is disposed by being supported by the target support member ST to face the base material BM, gas that will collide with the target TG may be supplied into the chamber through a first gas supply pipe PG1. For example, argon (Ar) gas may be supplied into the chamber through the first gas supply pipe PG1. The gas that will collide with the target TG, which is supplied into the chamber through the first gas supply pipe PG1, may be ionized into plasma. The ionized gas may collide with the target TG. When the ionized gas collides with the target TG, atoms of the first metal element and the second metal element, or the like may be separated from the target TG and move to the base material BM. In other words, the ionized gas may collide with the target TG, and thus metal atoms or the like may be separated from the target TG.

In an embodiment, while the gas, which will collide with the target TG, is being supplied into the chamber through the first gas supply pipe PG1, reactive gas containing a non-metal element may be supplied into the chamber through a second gas supply pipe PG2. For example, oxygen gas may be supplied into the chamber through the second gas supply pipe PG2. The reactive gas supplied into the chamber through the second gas supply pipe PG2 may react with metal atoms or the like separated from the target TG.

Through this process (e.g., supplying the oxygen gas into the chamber and the above-mentioned subsequent operations), while the first metal element-based material and the second metal element-based material are being formed, the second metal element-based material may be solid-solutioned into the first metal element-based material.

The buffer layer 200 and the exposed layer 300 may have the same or similar components, except for the content of the metal element and the content of the non-metal element, as described above. Therefore, a flow rate of the reactive gas supplied into the chamber may be controlled, so that the buffer layer 200 may be disposed to be deposited on the base material BM, and the exposed layer 300 may be disposed to be deposited on the buffer layer 200 disposed on the base material BM.

In FIG. 3, the buffer layer 200 may be disposed to be deposited on the base material BM by physical vapor deposition of FIG. 2. For example, in the physical vapor deposition of FIG. 2, the flow rate of the oxygen gas supplied into the chamber through the second gas supply pipe PG2 may be controlled to have the oxygen content included in the buffer layer 200, whereby the buffer layer 200 may be disposed to be deposited on the base material BM.

In FIG. 4, after the buffer layer 200 is disposed on the base material BM, the exposed layer 300 may be disposed to be deposited on the buffer layer 200 by physical vapor deposition of FIG. 2. For example, in the physical vapor deposition of FIG. 2, the flow rate of the oxygen gas supplied into the chamber through the second gas supply pipe PG2 may be controlled to have the oxygen content included in the exposed layer 300, whereby the exposed layer 300 may be disposed to be deposited on the buffer layer 200.

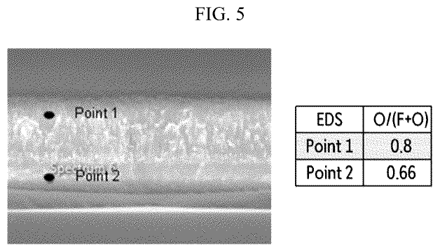

FIG. 5 is a Scanning Electron Microscope (SEM)-Energy Dispersive Spectroscopy (EDS) analysis result of an example of the coating structure of FIG. 1. In the example of the coating structure 100 of FIG. 1, the coating structure 100 is formed by reactive sputtering or electron beam physical vapor deposition using yttrium as a first metal element, yttrium oxide as a first metal element-based material, cerium as a second metal element and cerium oxide as a second metal element-based material. In other words, the buffer layer 200 and the exposed layer 300 are formed by solid-solutioning cerium oxide into yttrium oxide by reactive sputtering or electron beam physical vapor deposition, and the buffer layer 200 and the exposed layer 300 include yttrium, cerium, and oxygen. In addition, the content of cerium and yttrium in the buffer layer 200 is higher than that in the exposed layer 300. In addition, the oxygen content in the exposed layer 300 is higher than that in the buffer layer 200.

In FIG. 5, an example of the coating structure 100 of FIG. 1 is fluorinated and the fraction of oxygen among non-metal elements is analyzed by SEM-EDS. In other words, the content of oxygen relative to the total content of fluorine and oxygen, which are non-metal elements, is analyzed. As a result of the analysis, the fraction of oxygen among the non-metal elements at point 1 of the exposed layer 300 is 0.8, and the fraction of oxygen among the non-metal elements at point 2 of the buffer layer 200 is 0.66, showing different fractions. In addition, the fraction of oxygen among the non-metal elements at point 2 of the buffer layer 200 is lower than the fraction of oxygen among the non-metal elements at point 1 of the exposed layer 300, and diffusion of fluorine in the exposed layer 300 is prevented and thus diffusion of fluorine into the buffer layer 200 is blocked.

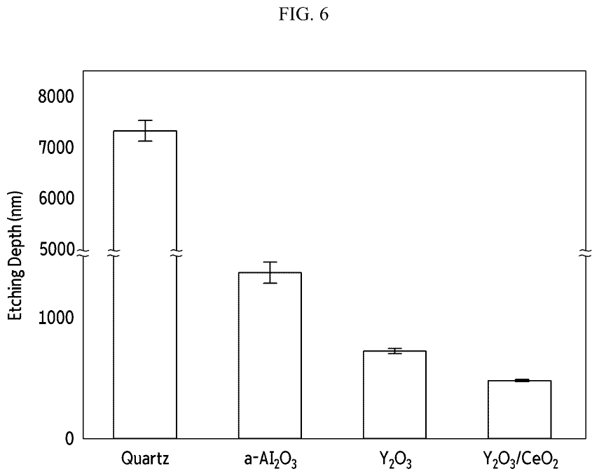

FIG. 6 illustrates etching test results of other coating structures and an example of the coating structure of FIG. 1.

Other coating structures include a coating structure in which the base material is coated with quartz as a coating material, a coating structure in which the base material is coated with alpha aluminum oxide (α-Al₂O₃) as a coating material, and a coating structure in which the base material is coated with yttrium oxide as a coating material.

In FIG. 6, the etching test is carried out in a high-power plasma etching apparatus, and is carried out at 70% output of the high-power plasma etching apparatus.

In FIG. 6, the coating structure in which the base material is coated with alpha aluminum oxide as a coating material has a smaller etching amount than the coating structure in which the base material is coated with quartz as a coating material. In an embodiment, the coating structure in which the base material is coated with yttrium oxide as a coating material has a smaller etching amount than the coating structure in which the base material is coated with alpha aluminum oxide as a coating material. In addition, an example of the coating structure 100 of FIG. 1 has a smaller etching amount than the coating structure in which the base material is coated with yttrium oxide as a coating material. In addition, an example of the coating structure 100 of FIG. 1 has improved etching resistance by about 40% or more than the coating structure in which the base material is coated with yttrium oxide as a coating material.

As described above, in FIG. 6, the etching test is performed at 70% output power of the high-power plasma etching apparatus. In addition, an example of the coating structure 100 of FIG. 1 may be applied to a heater of a chemical vapor deposition apparatus. In addition, since a plasma cleaning process of the chemical vapor deposition apparatus is performed at an output power lower than 70% output power of the high-power plasma etching apparatus, the increase in etching resistance characteristics of an example of the coating structure 100 of FIG. 1 is expected to show remarkable results.

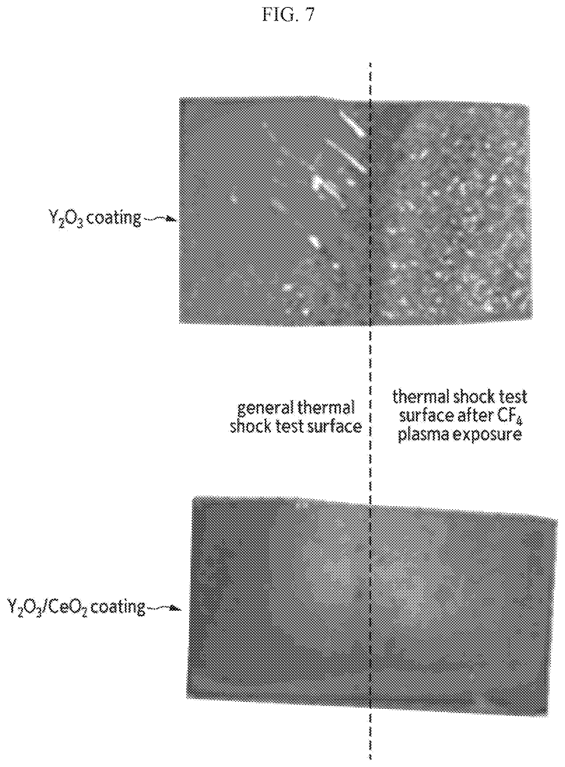

FIG. 7 illustrates results of thermal shock tests for another coating structure and an example of the coating structure of FIG. 1.

Another coating structure is a coating structure in which the base material is coated with yttrium oxide as a coating material by electron beam physical vapor deposition.

In addition, surfaces of one half of another coating structure and one half of the coating structure 100 of FIG. 1 were exposed under the atmosphere of low-power carbon tetrafluoride (CF₄) for 30 minutes for composition of a fluoride layer, and those of the other half of another coating structure and the other half of the coating structure 100 of FIG. 1 were not so.

In FIG. 7, a box-type electric furnace is used for the thermal shock test. Another coating structure and the coating structure 100 of FIG. 1 are heated at 600° C. for 10 minutes, and then exposed to room temperature for 10 minutes. This cycle is repeated 5 times.

In FIG. 7, in the coating structure having the base material coated with the yttrium oxide as a coating material, cracks and particles may occur in both a first half in which the fluoride layer is not formed and a second half in which the fluoride layer is formed.

In addition, in an example of the coating structure 100 of FIG. 1, cracks and particles do not occur in both the half in which the fluoride layer is not formed and the half in which the fluoride layer is formed.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, the embodiments as described above are not restrictive but illustrative in all respects.

What is claimed is:

1. A coating structure comprising:
a buffer layer on a base material; and
an exposed layer on the buffer layer,
wherein each of the buffer layer and the exposed layer includes a composite material including at least a first metal element, a second metal element, and a non-metal element.

2. The coating structure of claim 1, wherein a content of the metal element in the buffer layer is greater than a content of the metal element in the exposed layer, and
wherein a content of the non-metal element in the exposed layer is greater than a content of the non-metal element in the buffer layer.

3. The coating structure of claim 1, wherein each of the buffer layer and the exposed layer comprises oxygen, and
wherein the buffer layer and the exposed layer are formed by solid-solutioning a second metal element-based material including the second metal element and the oxygen into a first metal element-based material including the first metal element and the oxygen.

4. The coating structure of claim 3, wherein, by physical vapor deposition (PVD), the second metal element-based material is solid-solutioned into the first metal element-based material and the buffer layer is deposited on the base material.

5. The coating structure of claim 4, wherein, by the PVD, the second metal element-based material is solid-solutioned into the first metal element-based material and the exposed layer is deposited on the buffer layer.

6. The coating structure of claim 3, wherein the first metal element is yttrium (Y).

7. The coating structure of claim 6, wherein the first metal element-based material includes at least one of yttrium oxide (Y₂O₃) and yttrium oxyfluoride (YOF).

8. The coating structure of claim 3, wherein the second metal element includes at least one of cerium (Ce), aluminum (Al), and hafnium (Hf).

9. The coating structure of claim 8, wherein the second metal element-based material includes at least one of cerium oxide (CeO₂), aluminum oxide (Al₂O₃), and aluminum oxyfluoride (AlOF).

10. The coating structure of claim 3, wherein a fraction of the oxygen in the buffer layer is 0.1 or more and 0.3 or less.

11. The coating structure of claim 10, wherein a fraction of the oxygen in the exposed layer is 0.5 or more and 0.8 or less.

12. The coating structure of claim 1, wherein a thickness of the buffer layer is 20 nm or more and 500 nm or less.

13. The coating structure of claim 1, wherein a thickness of the exposed layer is 2 μm or more and 10 μm or less.

14. A coating structure comprising:
a buffer layer on a base material in a heater of a chemical vapor deposition apparatus; and
an exposed layer on the buffer layer,
wherein each of the buffer layer and the exposed layer includes at least a first metal element, a second metal element, and oxygen,
wherein a content of the metal element in the buffer layer is greater than a content of the metal element in the exposed layer, and
wherein a content of the oxygen in the exposed layer is greater than a content of the oxygen in the buffer layer.

15. The coating structure of claim 14, wherein the buffer layer and the exposed layer are formed by solid-solutioning a second metal element-based material including the second metal element and the oxygen into a first metal element-based material including the first metal element and the oxygen.

16. The coating structure of claim 15, wherein the first metal element is yttrium (Y), and
wherein the first metal element-based material includes at least one of yttrium oxide (Y₂O₃) and yttrium oxyfluoride (YOF).

17. The coating structure of claim 15, wherein the second metal element includes at least one of cerium (Ce), aluminum (Al), and hafnium (Hf), and
wherein the second metal element-based material includes at least one of cerium oxide (CeO₂), aluminum oxide (Al₂O₃), and aluminum oxyfluoride (AlOF).

18. The coating structure of claim 14, wherein a fraction of the oxygen in the buffer layer is 0.1 or more and 0.3 or less, and
wherein a fraction of the oxygen in the exposed layer is 0.5 or more and 0.8 or less.

19. The coating structure of claim 14, wherein a thickness of the buffer layer is 20 nm or more and 500 nm or less, and
wherein a thickness of the exposed layer is 2 μm or more and 10 μm or less.

20. A coating structure comprising:
a buffer layer on a base material; and
an exposed layer on the buffer layer,
wherein each of the buffer layer and the exposed layer includes at least a first metal element, a second metal element, and oxygen,
wherein a content of the metal element in the buffer layer is greater than a content of the metal element in the exposed layer,
wherein a content of the oxygen in the exposed layer is greater than a content of the oxygen in the buffer layer,
wherein the buffer layer and the exposed layer are formed by solid-solutioning a second metal element-based material including the second metal element and the oxygen into a first metal element-based material including the first metal element and the oxygen,
wherein the first metal element is yttrium (Y),
wherein the first metal element-based material includes at least one of yttrium oxide (Y₂O₃) and yttrium oxyfluoride (YOF),
wherein the second metal element includes at least one of cerium (Ce), aluminum (Al), and hafnium (Hf),
wherein the second metal element-based material includes at least one of cerium oxide (CeO₂), aluminum oxide (Al₂O₃), and aluminum oxyfluoride (AlOF),
wherein a fraction of the oxygen in the buffer layer is 0.1 or more and 0.3 or less,
wherein a fraction of the oxygen in the exposed layer is 0.5 or more and 0.8 or less,
wherein a thickness of the buffer layer is 20 nm or more and 500 nm or less, and
wherein a thickness of the exposed layer is 2 μm or more and 10 μm or less.
